(19) United States
(12) Patent Application Publication
(10) Pub. No.: US 2026/0114136 A1
(43) Pub. Date: Apr. 23, 2026

(54) DISPLAY APPARATUS AND ELECTRONIC DEVICE

(71) Applicant: Samsung Display Co., Ltd., YONGIN-SI (KR)

(72) Inventors: CHAUNGI CHOI, Yongin-si (KR); BOKWANG SONG, Yongin-si (KR)

(21) Appl. No.: 19/359,976

(22) Filed: Oct. 16, 2025

(30) Foreign Application Priority Data
Oct. 21, 2024 (KR) 10-2024-0144264

(51) Int. Cl. H10K 59/124; H10K 50/19; H10K 59/123; H10K 59/131

(52) U.S. Cl. CPC H10K 59/124; H10K 50/19; H10K 59/123; H10K 59/131

(57) ABSTRACT

A display apparatus includes a substrate. A first electrode is on the substrate. A second electrode is arranged to face the first electrode. A first emission layer is arranged between the first electrode and the second electrode. A second emission layer is arranged to have a first region overlapping at least the first emission layer. A charge generation layer is arranged between the first emission layer and the second emission layer. The charge generation layer includes a charge connection region that does not overlap the first emission layer in a thickness direction of the substrate and overlaps the second emission layer in the thickness direction of the substrate.

### CROSS-REFERENCE TO RELATED APPLICATION

This application claims priority under 35 U.S.C. §119 to Korean Patent Application No. 10-2024-0144264, filed on October 21, 2024 in the Korean Intellectual Property Office, the disclosure of which is incorporated by reference in its entirety herein.

### TECHNICAL FIELD

One or more embodiments of the present disclosure relate to a display apparatus.

### DISCUSSION OF RELATED ART

Display apparatuses have been applied to an increasing variety of electronic devices along with the advancement of the information society. Additionally, display apparatuses have become thinner and more lightweight for increased portability and user convenience.

Also, as fields of using display apparatuses increase and technology utilizing the display apparatus is developed, a demand for high image-quality characteristics and high-resolution characteristics has increased.

In addition, as display apparatuses are developed to have high-resolution, there is a limitation in increasing image quality and precisely controlling optical characteristics.

### SUMMARY

One or more embodiments of the present disclosure provide a display apparatus capable of increasing image quality and precisely controlling optical characteristics.

According to an embodiment of the present disclosure, a display apparatus includes a substrate. A first electrode is on the substrate. A second electrode is arranged to face the first electrode. A first emission layer is arranged between the first electrode and the second electrode. A second emission layer is arranged to have a first region overlapping at least the first emission layer. A charge generation layer is arranged between the first emission layer and the second emission layer. The charge generation layer includes a charge connection region that does not overlap the first emission layer in a thickness direction of the substrate and overlaps the second emission layer in the thickness direction of the substrate.

In an embodiment, the second emission layer may extend past at least an edge of the first emission layer and includes a second region that does not overlap the first emission layer in the thickness direction of the substrate.

In an embodiment, the second emission layer may have a greater area in a plan view than an area of the first emission layer in the plan view.

In an embodiment, one or more insulating layers having a contact hole may be arranged on the substrate, and the charge connection region of the charge generation layer may correspond to the contact hole.

In an embodiment, the contact hole may be arranged to be spaced apart from the first electrode in a plan view.

In an embodiment, the charge connection region of the charge generation layer may be electrically connected to one or more conductive layers.

In an embodiment, the charge connection region of the charge generation layer may be electrically connected to one or more transistors.

According to an embodiment of the present disclosure, a display apparatus includes a substrate. A first electrode is on the substrate. A second electrode is arranged to face the first electrode. A first emission layer is arranged between the first electrode and the second electrode. A second emission layer is arranged to have a first region overlapping at least the first emission layer. An intermediate electrode is arranged between the first emission layer and the second emission layer. The intermediate electrode includes a connection region that does not overlap the first emission layer in a thickness direction of the substrate and overlaps the second emission layer in the thickness direction of the substrate.

In an embodiment, the second emission layer may extend past at least an edge of the first emission layer and includes a second region of the second emission layer that does not overlap the first emission layer in the thickness direction of the substrate.

In an embodiment, the second emission layer may have a greater area in a plan view than area of the first emission layer in the plan view.

In an embodiment, one or more insulating layers having a contact hole may be arranged on the substrate, and the connection region of the intermediate electrode may correspond to the contact hole.

In an embodiment, the contact hole may be arranged to be spaced apart from the first electrode in a plan view.

In an embodiment, the connection region of the intermediate electrode may be electrically connected to one or more conductive layers in a region corresponding to the contact hole.

In an embodiment, the connection region of the intermediate electrode may be arranged to be electrically connected to one or more transistors.

In an embodiment, the intermediate electrode may control one of the first emission layer and the second emission layer to selectively emit light.

According to an embodiment of the present disclosure, a display apparatus includes a substrate. A first electrode is on the substrate. A second electrode is arranged to face the first electrode. A first emission layer is arranged between the first electrode and the second electrode. A second emission layer is arranged to have a first region overlapping at least the first emission layer. An insulating layer has a contact hole that does not overlap the first emission layer in a thickness direction of the substrate and overlaps the second emission layer in the thickness direction of the substrate.

In an embodiment, the display apparatus may include a charge generation layer arranged between the first emission layer and the second emission layer, and a region of the charge generation layer may be arranged to correspond to the contact hole.

In an embodiment, the charge generation layer may be electrically connected to a conductive layer or a transistor via the contact hole.

In an embodiment, the display apparatus may include an intermediate electrode arranged between the first emission layer and the second emission layer, and a region of the intermediate electrode may be arranged to correspond to the contact hole.

In an embodiment, the intermediate electrode may be electrically connected to a conductive layer or a transistor via the contact hole.

According to an embodiment of the present disclosure, an electronic device comprises a display apparatus. The display apparatus comprises a substrate. A first electrode is on the substrate. A second electrode is arranged to face the first electrode. A first emission layer is arranged between the first electrode and the second electrode. A second emission layer is arranged to have a region overlapping at least the first emission layer. A charge generation layer is arranged between the first emission layer and the second emission layer. The charge generation layer includes a charge connection region that does not overlap the first emission layer in a thickness direction of the substrate and overlaps the second emission layer in the thickness direction of the substrate.

According to an embodiment of the present disclosure, an electronic device comprises a display apparatus. The display apparatus comprises a substrate. A first electrode is on the substrate. A second electrode is arranged to face the first electrode. A first emission layer is arranged between the first electrode and the second electrode. A second emission layer is arranged to have a region overlapping at least the first emission layer. An intermediate electrode is arranged between the first emission layer and the second emission layer. The intermediate electrode includes a connection region that does not overlap the first emission layer in a thickness direction of the substrate and overlaps the second emission layer in the thickness direction of the substrate.

According to an embodiment of the present disclosure, an electronic device comprises a display apparatus. The display apparatus comprises a substrate. A first electrode is on the substrate. A second electrode is arranged to face the first electrode. A first emission layer is arranged between the first electrode and the second electrode. A second emission layer is arranged to have a region overlapping at least the first emission layer. An insulating layer has a contact hole that does not overlap the first emission layer in a thickness direction of the substrate and overlaps the second emission layer in the thickness direction of the substrate.

Other aspects, features and advantages other than those described above will become apparent from the following detailed description of the drawings, claims and disclosure.

### BRIEF DESCRIPTION OF THE DRAWINGS

These and/or other aspects will become apparent and more readily appreciated from the following description of the embodiments, taken in conjunction with the accompanying drawings in which:

FIG. 1 is a cross-sectional view of a display apparatus according to an embodiment of the present disclosure;

FIG. 2 is an enlarged view of an example of expanding region L in FIG. 1 according to an embodiment of the present disclosure;

FIG. 3 is an enlarged view of an example of expanding region M in FIG. 1 according to an embodiment of the present disclosure;

FIG. 4 is a cross-sectional view of a display apparatus according to an embodiment of the present disclosure;

FIG. 5 is a schematic cross-sectional view of a display apparatus according to an embodiment of the present disclosure;

FIG. 6 is a schematic plan view showing the display apparatus of FIG. 5 from one direction according to an embodiment of the present disclosure;

FIG. 7 is a schematic cross-sectional view of a display apparatus according to an embodiment of the present disclosure;

FIG. 8 is a schematic cross-sectional view of a display apparatus according to an embodiment of the present disclosure;

FIG. 9 is a schematic diagram illustrating an example of a charge generation layer and a transistor in the display apparatus of FIG. 8 according to an embodiment of the present disclosure;

FIG. 10 is a schematic cross-sectional view of a display apparatus according to an embodiment of the present disclosure;

FIG. 11 is a schematic diagram illustrating an example of a charge generation layer and a transistor in the display apparatus of FIG. 10 according to an embodiment of the present disclosure;

FIG. 12 is a schematic cross-sectional view of a display apparatus according to an embodiment of the present disclosure;

FIGS. 13 to 17 are diagrams schematically illustrating a method of manufacturing a display apparatus, according to embodiments of the present disclosure;

FIG. 18 is a schematic cross-sectional view of a display apparatus according to an embodiment of the present disclosure; and

FIG. 19 is a schematic diagram illustrating an example of a charge generation layer and a transistor in the display apparatus of FIG. 18 according to an embodiment of the present disclosure.

### DETAILED DESCRIPTION OF EMBODIMENTS

As the present disclosure allows for various changes and numerous embodiments, particular non-limiting embodiments will be illustrated in the drawings and described in detail in the written description. The attached drawings for illustrating one or more embodiments are referred to provide a sufficient understanding, the merits thereof, and the objectives accomplished by the implementation. However, embodiments of the present disclosure may have different forms and should not be construed as being limited to the descriptions set forth herein.

While such terms as "first," "second," etc., may be used to describe various components, such components are not be limited to the above terms. The above terms are used only to distinguish one component from another.

An expression used in the singular encompasses the expression of the plural, unless it has a clearly different meaning in the context.

In the present specification, it is to be understood that the terms "including," "having," and "comprising" are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

It will be understood that when a layer, region, or component is referred to as being "formed on" another layer, region, or component, it may be directly or indirectly formed on the other layer, region, or component. That is, for example, intervening layers, regions, or components may be present. When a layer, region, or component is referred to as being "formed directly on" another layer, region, or component, no intervening elements may be present.

Sizes of components in the drawings may be exaggerated for convenience of explanation. In some embodiments, since sizes and thicknesses of components in the drawings may be arbitrarily illustrated for convenience of explanation, the following embodiments are not necessarily limited thereto.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that cross each other but are not perpendicular to one another.

When a certain embodiment is implemented differently, a specific process order may be performed differently from the described order. For example, two consecutively described processes may be performed substantially at the same time or performed in an order opposite to the described order.

Embodiments will be described below in more detail with reference to the accompanying drawings. Those components that are the same or are in correspondence are rendered the same reference numeral regardless of the figure number, and redundant explanations may be omitted for economy of explanation.

The present disclosure concerns a display apparatus that includes a charge generation layer disposed between a first emission layer and a second emission layer. The charge generation layer includes a charge connection region that does not overlap the first emission layer in a thickness direction of the substrate and overlaps the second emission layer in the thickness direction of the substrate. The charge generation layer releases charges that are accumulated in the charge generation layer through the charge connection region. Therefore, the color emitted when the display apparatus is driven may be precisely controlled and the display apparatus may have increased image quality. In some embodiments, the charges accumulated in the charge generation layer may be selectively discharged through at least one transistor. In some embodiments, the charge generation layer may correspond to a contact hole defined in an insulating layer.

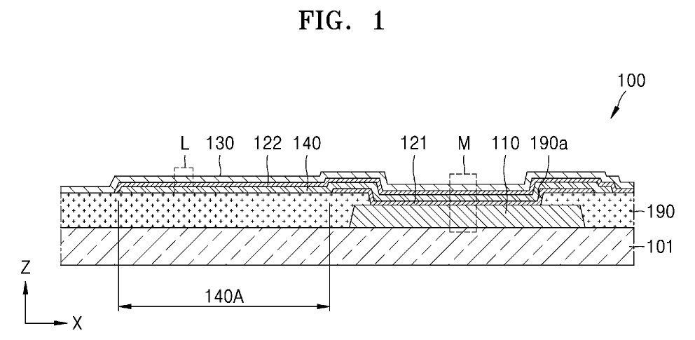

FIG. 1 is a cross-sectional view of a display apparatus according to an embodiment of the present disclosure.

Referring to FIGS. 1 to 3, a display apparatus 100 may include a substrate 101, a first electrode 110, a second electrode 130, a first emission layer 121, a second emission layer 122, and a charge generation layer (CGL) 140.

The display apparatus 100 may be of various types, for example, an organic light emitting display (OLED) apparatus. The display apparatus 100 according to an embodiment of the present disclosure may be used as a portable electronic apparatus such as a mobile phone, a smartphone, a tablet personal computer (PC), a mobile communication terminal, an electronic notebook, an electronic book, a portable multimedia player (PMP), a navigation terminal, an ultra-mobile PC (UMPC), etc., and also used in various products such as a television, a laptop computer, a monitor, a billboard, internet of things (IoT), etc. In another example, the display apparatus 100 may be applied to a wearable device such as a smart watch, a watch phone, a glasses-type display, and a head mounted display (HMD). In some embodiments, the display apparatus 100 according to an embodiment may be applied to a dashboard of a vehicle, a center information display (CID) in a center fascia or dashboard of a vehicle, a rear-view mirror display that replaces a side-view mirror of a vehicle, a display screen in a rear side of a front seat as an entertainment for the back seat in a vehicle. However, embodiments of the present disclosure are not necessarily limited thereto and the electronic device that the display apparatus 100 may be applied to may be various different small-sized, medium-sized or large-sized electronic devices.

The substrate 101 may include various materials. In an embodiment, the substrate 101 may include glass, metal, an organic material, or other materials.

In an embodiment, the substrate 101 may include a flexible material. For example, the substrate 101 may be formed to be easily curved, bendable, foldable, rollable or otherwise deformable for increased portability and user convenience.

In an embodiment, the substrate 101 may include ultra-thin glass, metal, or plastic. For example, in an embodiment in which plastic is used, the substrate 101 may include polyimide (PI), and in some examples, the substrate 101 may include at least one of polystyrene, polyvinyl alcohol, polymethyl methacrylate, polyether sulfone, polyacrylate, polyetherimide, polyethylene naphthalate, polyethylene terephthalate, polyphenylene sulfide, polyarylate, polycarbonate, triacetate cellulose, and cellulose acetate propionate.

In some embodiments, the substrate 101 may include one or more layers, for example, a multi-layered structure. For example, the substrate 101 may include an organic layer (e.g., a resin-based material) and an inorganic layer, and in more detail, may include a structure in which an inorganic layer is arranged between two organic layers.

In an embodiment, one or more insulating layers may be arranged on the substrate 101.

In an embodiment, one or more thin film transistors may be arranged on the substrate 101.

The first electrode 110 may have various shapes, for example, may be patterned in an island shape. However, embodiments of the present disclosure are not necessarily limited thereto.

The first electrode 110 may include various conductive materials. For example, in an embodiment the first electrode 110 may include at least one selected from the group consisting of transparent conductive oxides such as indium tin oxide (ITO), indium zinc oxide (IZO), zinc oxide (ZnO), indium oxide (In₂O₃), indium gallium oxide (IGO), and aluminum zinc oxide (AZO). In some embodiments, the first electrode 110 may include metal having high reflectivity such as argentum (Ag).

In an embodiment, the first electrode 110 may have a multi-layered structure, for example, a multi-layered structure including above-described materials, such as at least one layer including the transparent conductive oxide such as ITO, IZO, ZnO, In₂O₃, IGO, and AZO, and at least one layer including metal such as Ag.

In an embodiment, the first electrode 110 may include triple or more layers, such as a metal layer between two transparent conductive oxide layers, for example, a triple-layered structure including ITO/Ag/ITO.

The second electrode 130 may be arranged to face the first electrode 110. The second electrode 130 may include various conductive materials. For example, in an embodiment the second electrode 130 may include lithium (Li), calcium (Ca), lithium fluoride (LiF), aluminum (Al), magnesium (Mg), or argentum (Ag), at least one of which is formed in a single layer or multiple layers, and may include an alloy material including at least two of the above materials.

The first emission layer 121 may be arranged between the first electrode 110 and the second electrode 130 (e.g., in the Z direction). In an embodiment, the first emission layer 121 may include, for example, an organic emission layer, and may include low-molecular weight organic material or a high-molecular weight organic material.

In an embodiment, a pixel-defining layer 190 may be arranged on the first electrode 110.

The pixel-defining layer 190 is arranged so as not to cover a certain region of the first electrode 110, and the first emission layer 121 may be arranged so as to overlap the region of the first electrode 110, which is not covered (e.g. exposed) by the pixel-defining layer 190, for example, an opening 190a of the pixel-defining layer 190. For example, in an embodiment, the opening 190a may expose a central portion of the first electrode 110 and may cover lateral ends of the first electrode 110.

The pixel-defining layer 190 may include various insulating materials. For example, in an embodiment the pixel-defining layer 190 may include an organic material, such as one or more organic insulating materials selected from the group consisting of polyimide, polyamide, acrylic resin, benzocyclobutene, and phenol resin and may be formed by a method such as spin coating, etc.

The second emission layer 122 may be arranged between the first electrode 110 and the second electrode 130 (e.g., in the Z direction).

In some embodiments, the second emission layer 122 may be arranged so as to at least partially overlap the first emission layer 121 (e.g., in the Z direction).

For example, in an embodiment the display apparatus 100 has a structure in which two or more emission layers overlap each other, such as a tandem-type structure in which the first emission layer 121 and the second emission layer 122 overlap each other (e.g., in the Z direction). The display apparatus 100 of an embodiment may increase a luminance and lifespan by applying a structure in which the first emission layer 121 and the second emission layer 122 overlap each other (e.g., in the Z direction).

In some embodiments, the second emission layer 122 may be arranged so that a region of the second emission layer 122 may not overlap the first emission layer 121 (e.g., in the Z direction). For example, the second emission layer 122 may extend past at least an edge of the first emission layer 121 to include a region of the second emission layer 122 that does not overlap the first emission layer 121.

In an embodiment, the second emission layer 122 may include, for example, an organic emission layer, such as a low-molecular weight organic material or a high-molecular organic material.

Types of the first emission layer 121 and the second emission layer 122 may be variously selected.

For example, in an embodiment the color emitted from the second emission layer 122 may be the same as the color emitted from the first emission layer 121.

In some embodiments, the color emitted from the second emission layer 122 may be different from the color emitted from the first emission layer 121.

The CGL 140 may be arranged between the first emission layer 121 and the second emission layer 122 (e.g., in the Z direction). In some embodiments, the CGL 140 may include a charge connection region 140A that does not overlap the first emission layer 121 (e.g., in a thickness direction of the substrate 101, such as the Z direction) and overlaps the second emission layer 122 (e.g., in a thickness direction of the substrate 101, such as the Z direction). Detailed descriptions are provided later.

The CGL 140 is arranged between the first emission layer 121 and the second emission layer 122 to control generation or movement of charges in the first emission layer 121 and the second emission layer 122. For example, the CGL 140 may control a balance of the charges.

In an embodiment, the CGL 140 includes an N-type or P-type charge generation layer, such as an N-type charge generation layer and a P-type charge generation layer.

In an embodiment, two devices may be implemented based on the CGL 140.

In more detailed example, the first electrode 110, the first emission layer 121, and the CGL 140 may be implemented as one device, and the first electrode 110 and the CGL 140 may function as electrodes relative to each other, for example, the first electrode 110 may function as an anode and the CGL 140 may function as a cathode.

In some embodiments, the second electrode 130, the second emission layer 122, and the CGL 140 may be implemented as one device, and the second electrode 130 and the CGL 140 may function as electrodes relative to each other, for example, the second electrode 130 may function as a cathode and the CGL 140 may function as an anode.

The charge connection region 140A of the CGL 140 may include at least a region that does not overlap the first emission layer 121 and overlaps the second emission layer 122.

At least some of the charges accumulated in the CGL 140 may be discharged at least at one point in time through the charge connection region 140A of the CGL 140.

In an embodiment, the charge connection region 140A of the CGL 140 may be connected to the conductive layer via at least one region, and may be connected to a connection electrode region. In some embodiments, the charge connection region 140A of the CGL 140 may be connected to a transistor, such as a thin film transistor, and may control discharging of the charges from the CGL 140 at desired time through the control from the thin film transistor.

As described above, the display apparatus 100 according to an embodiment includes the structure in which the first emission layer 121 and the second emission layer 122 overlap each other (e.g., in the Z direction). When controlling the light emission from the first emission layer 121 and the second emission layer 122, residual light emission that is unnecessary may occur. For example, while a color (e.g., black) is implemented by the display apparatus 100, the generation and accumulation of charges in the CGL 140 increase, and when the color implemented by the display apparatus 100 is changed to white, unnecessary luminance generation (e.g., flashing) may occur due to the charges remaining in the CGL 140. In some embodiments, the charges remaining in the CGL 140 may be a limitation in precisely controlling the flow of charges to the first emission layer 121 and the second emission layer 122.

In an embodiment, the charges accumulated in the CGL 140 may be discharged through the charge connection region 140A of the CGL 140, and thus, a precision in the color emitted when the display apparatus 100 drives may be increased and the image quality may be increased.

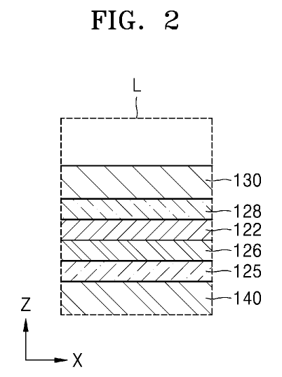

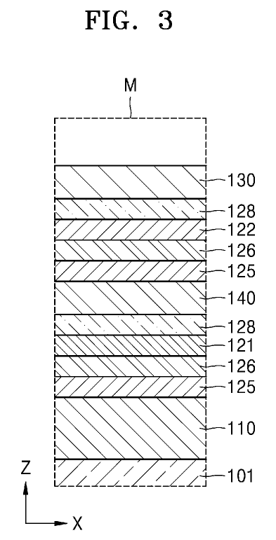

FIG. 2 is an example diagram showing enlarged view of region L in FIG. 1. FIG. 3 is an example diagram showing an enlarged view of region M in FIG. 1.

Referring to FIG. 2, one or more layers may be further included along with the second emission layer 122 between the CGL 140 and the second electrode 130 (e.g., in the Z direction), such as an electron transport layer 128, a hole transport layer 126, and a hole injection layer 125 may be arranged. However, this is an example, and one or more of the electron transport layer 128, the hole transport layer 126, and the hole injection layer 125 may be arranged. In an embodiment, an electron injection layer may be arranged between the second electrode 130 and the electron transport layer 128 (e.g., in the Z direction).

In some embodiments, referring to FIG. 3, one or more layers may be further included along with the first emission layer 121 between the CGL 140 and the first electrode 110 (e.g., in the Z direction), such as the electron transport layer 128, the hole transport layer 126, and the hole injection layer 125 may be arranged. However, this is an example, and one or more of the electron transport layer 128, the hole transport layer 126, and the hole injection layer 125 may be arranged. In an embodiment, an electron injection layer may be arranged between the CGL 140 and the electron transport layer 128 (e.g., in the Z direction).

In some embodiments, the display apparatus 100 may further include an encapsulation portion arranged to partially or entirely cover the second electrode 130. The encapsulation portion may include a glass material or a plastic material.

In some embodiments, the encapsulation portion may include one or more encapsulation layers. In an embodiment, the encapsulation portion may include one or more inorganic layers or one or more organic layers, and in an example, the encapsulation portion may include a structure in which an inorganic layer and an organic layer are alternately stacked one or more times, such as a structure in which the inorganic layer and the organic layer are alternately stacked multiple times.

In some embodiments, the encapsulation portion may be selectively applied to the embodiments described later.

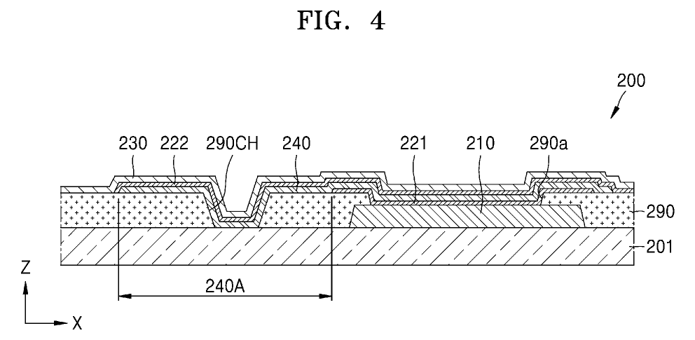

FIG. 4 is a cross-sectional view of a display apparatus according to an embodiment of the present disclosure.

Referring to FIG. 4, in an embodiment a display apparatus 200 may include a substrate 201, a first electrode 210, a second electrode 230, a first emission layer 221, a second emission layer 222, and a CGL 240. Hereinafter, differences from the above embodiment are described in detail for convenience of description.

The substrate 201 may include various materials. In an embodiment, the substrate 201 may include glass, metal, an organic material, or other materials, and may be modified and applied within a range substantially the same as or similar to that described in an embodiment shown in FIG. 1. Thus, detailed descriptions are omitted.

The first electrode 210 may have various shapes, for example, may be patterned in an island shape. For example, the first electrode 210 may be modified and applied within the range that is substantially the same as or similar to the descriptions provided in the above-described embodiment shown in FIG. 1, and thus detailed descriptions are omitted.

The second electrode 230 may be arranged to face the first electrode 210. The second electrode 230 may include various conductive materials. For example, the second electrode 230 may be modified and applied within the range that is substantially the same as or similar to the descriptions provided in an embodiment shown in FIG. 1, and thus detailed descriptions are omitted.

In some embodiments, the second electrode 230 may be arranged to correspond to and overlap a contact hole 290CH (e.g., in the Z direction) that is described later.

The first emission layer 221 may be arranged between the first electrode 210 and the second electrode 230 (e.g., in the Z direction). In an embodiment, the first emission layer 221 may include, for example, an organic emission layer, such as a low-molecular weight organic material or a high-molecular weight organic material.

In some embodiments, the first emission layer 221 may be arranged so as not to correspond to and overlap the contact hole 290CH (e.g., in the Z direction) that is described later.

The pixel-defining layer 290 may be arranged on the first electrode 210.

The pixel-defining layer 290 is arranged so as not to cover a certain region of the first electrode 210, and the first emission layer 221 may be arranged so as to overlap (e.g., in the Z direction) the region of the first electrode 210, which is not covered by the pixel-defining layer 290, for example, an opening 290a of the pixel-defining layer 290.

The pixel-defining layer 290 may include various insulating materials. For example, in an embodiment the pixel-defining layer 290 may include an organic material, such as one or more organic insulating materials selected from the group consisting of polyimide, polyamide, acrylic resin, benzocyclobutene, and phenol resin and may be formed by a method such as spin coating, etc.

In some embodiments, the pixel-defining layer 290 may include the contact hole 290CH having a depth corresponding to at least a partial thickness or total thickness of the pixel-defining layer 290. The contact hole 290CH may be spaced apart from the opening 290a in a plan view (e.g., in the -X direction) and may not overlap the opening 290a in a plan view (e.g., in the Z direction). In some embodiments, as such, the contact hole 290CH may be formed to be spaced apart from the first electrode 210 in a plan view (e.g., in the -X direction).

The second emission layer 222 may be arranged between the first electrode 210 and the second electrode 230 (e.g., in the Z direction).

In some embodiments, the second emission layer 222 may be arranged so as to at least partially overlap the first emission layer 221 (e.g., in the Z direction).

For example, the display apparatus 200 of an embodiment shown in FIG. 4 has a tandem-type structure in which two or more emission layers overlap each other, such as the first emission layer 221 and the second emission layer 222 overlap each other (e.g., in the Z direction).

The second emission layer 222 may be arranged so that the second emission layer 222 may not overlap the first emission layer 221 (e.g., in the Z direction) in a region.

In an embodiment, the second emission layer 222 may include, for example, an organic emission layer, such as a low-molecular weight organic material or a high-molecular organic material.

Types of the first emission layer 221 and the second emission layer 222 may be various. For example, in an embodiment the color emitted from the second emission layer 222 may be different from the color emitted from the first emission layer 221.

In some embodiments, the color emitted from the second emission layer 222 may be the same as the color emitted from the first emission layer 221.

In some embodiments, the second emission layer 222 may be arranged to correspond to and overlap the contact hole 290CH (e.g., in the Z direction).

The CGL 240 may be arranged between the first emission layer 221 and the second emission layer 222 (e.g., in the Z direction). In some embodiments, the CGL 240 may include a charge connection region 240A that does not overlap the first emission layer 221 (e.g., in the Z direction) and overlaps the second emission layer 222 (e.g., in the Z direction). Detailed descriptions are provided later.

The CGL 240 is arranged between the first emission layer 221 and the second emission layer 222 (e.g., in the Z direction) to control generation or movement of charges between the first emission layer 221 and the second emission layer 222, for example, to control a balance of the charges.

In an embodiment, the CGL 240 includes an N-type or P-type charge generation layer, such as an N-type charge generation layer and a P-type charge generation layer.

In an embodiment, two devices may be implemented based on the CGL 240. For example, the first electrode 210, the first emission layer 221, and the CGL 240 may be implemented as one device, and the first electrode 210 and the CGL 240 may function as electrodes relative to each other. For example, the first electrode 210 may function as an anode and the CGL 240 may function as a cathode. In some embodiments, the second electrode 230, the second emission layer 222, and the CGL 240 may be implemented as one device, and the second electrode 230 and the CGL 240 may function as electrodes relative to each other. For example, the second electrode 230 may function as a cathode and the CGL 240 may function as an anode.

The charge connection region 240A of the CGL 240 may include at least a region that does not overlap the first emission layer 221 (e.g., in the Z direction) and overlaps the second emission layer 222 (e.g., in the Z direction).

The charges accumulated in the CGL 240 may be discharged at least at one point in time through the charge connection region 240A of the CGL 240.

In an embodiment, the charge connection region 240A of the CGL 240 may be connected to the conductive layer in at least one region. In an embodiment, the charge connection region 240A may be connected to a connection electrode region. In some embodiments, the charge connection region 240A of the CGL 240 may be connected to a transistor, such as a thin film transistor, and may control the discharge of charges from the CGL 240 at desired time through the control of the thin film transistor.

In some embodiments, the charge connection region 240A may at least correspond to the contact hole 290CH, for example, may overlap the contact hole 290CH (e.g., in the Z direction). In an embodiment in which the charge connection region 240A corresponds to the contact hole 290CH, the charge discharging structure of the CGL 240 may be easily implemented while reducing or preventing interference of the first electrode 210 or the second electrode 230. For example, the charge discharge may be easily implemented through a region, in the charge connection region 240A of the CGL 240, corresponding to the contact hole 290CH.

Since the charges accumulated in the CGL 240 may be discharged through the charge connection region 240A of the CGL 240 in the display apparatus 200 according to an embodiment, such as the region corresponding to the contact hole 290CH, the precision of the color emitted during the driving of the display apparatus 200 may be increased and the image quality characteristics may be increased.

In an embodiment, as shown in FIGS. 2 and 3, one or more layers along with the second emission layer 222 may be further included between CGL 240 and the second electrode 230 (e.g., in the Z direction), such as one or more of an electron transport layer, a hole transport layer, and a hole injection layer. In some embodiments, one or more layers along with the first emission layer 221 may be further included between the CGL 240 and the first electrode 210 (e.g., in the Z direction), such as one or more of the electron transport layer, the hole transport layer, and the hole injection layer may be arranged.

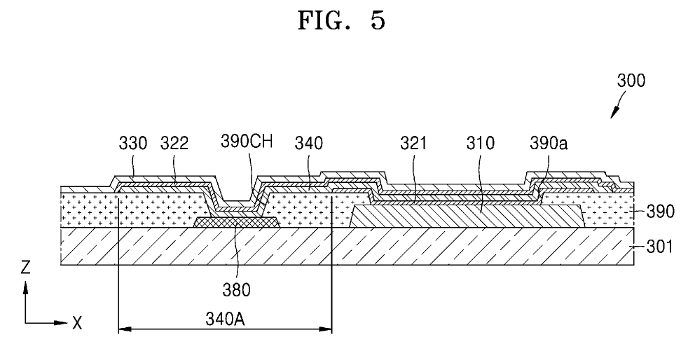

FIG. 5 is a schematic cross-sectional view of a display apparatus according to an embodiment of the present disclosure.

Referring to FIG. 5, in an embodiment a display apparatus 300 may include a substrate 301, a first electrode 310, a second electrode 330, a first emission layer 321, a second emission layer 322, a CGL 340, and a conductive layer 380. Hereinafter, differences from the above embodiments are described in detail for convenience of description.

The conductive layer 380 is different from the example of FIG. 4 and is described below.

One or more conductive layers 380 may be arranged to correspond to a contact hole 390CH of a pixel-defining layer 390. The conductive layer 380 may include various kinds of conductive materials, such as a metal material.

The CGL 340 may be arranged between the first emission layer 321 and the second emission layer 322 (e.g., in the Z direction). In some embodiments, the CGL 340 may include a charge connection region 340A that does not overlap the first emission layer 321 (e.g., in the Z direction) and overlaps the second emission layer 322 (e.g., in the Z direction).

The charge connection region 340A of the CGL 340 may include a region that at least does not overlap the first emission layer 321 (e.g., in the Z direction) and overlaps the second emission layer 322 (e.g., in the Z direction).

The charges accumulated in the CGL 340 may be discharged at least at one point in time through the charge connection region 340A of the CGL 340.

The charge connection region 340A of the CGL 340 may be connected to (e.g., electrically connected thereto) the conductive layer 380 in at least one region. For example, as shown in FIG. 5, the charge connection region 340A may be electrically connected to the conductive layer 380 by being in direct contact with the conductive layer 380. In an embodiment, the charge connection region 340A may correspond to at least the contact hole 390CH and may overlap the contact hole 390CH (e.g., in the Z direction), and may be connected to (e.g., electrically connected to) the conductive layer 380 via the contact hole 390CH.

Since the charge connection region 340A is connected to (e.g., electrically connected to) the conductive layer 380 via the contact hole 390CH, the charge discharging structure of the CGL 340 may be easily implemented while reducing or preventing the interference of the first electrode 310 or the second electrode 330. For example, the charge connection region 340A of the CGL 340 is connected to (e.g., electrically connected to) the conductive layer 380 via the contact hole 390CH, and thus, the discharging of charges from the CGL 340 to the conductive layer 380 may be easily implemented.

Since the charges accumulated in the CGL 340 may be discharged to the conductive layer 380 through the charge connection region 340A of the CGL 340 in the display apparatus 300 according to an embodiment, such as the region corresponding to the contact hole 390CH, the precision of the color emitted during the driving of the display apparatus 300 may be increased and the image quality characteristics may be increased.

In an alternative embodiment, as shown in FIGS. 2 and 3, one or more layers along with the second emission layer 322 may be further included between the CGL 340 and the second electrode 330 (e.g., in the Z direction), such as one or more of an electron transport layer, a hole transport layer, and a hole injection layer. In some embodiments, one or more layers along with the first emission layer 321 may be further included between the CGL 340 and the first electrode 310 (e.g., in the Z direction), such as one or more of the electron transport layer, the hole transport layer, and the hole injection layer may be arranged.

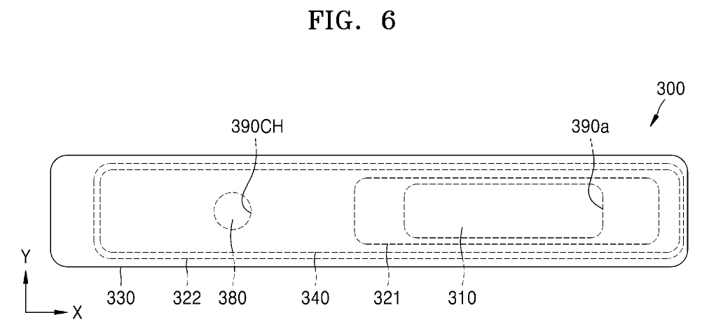

FIG. 6 is a schematic plan view showing an example of the display apparatus of FIG. 5 seen in one direction.

For example, FIG. 6 shows an example seen from above (e.g., a plan view) based on FIG. 5.

Referring to FIG. 6, in an embodiment the second emission layer 322, rather than at least the first emission layer 321, may be formed to have an extending region in at least one region, for example, the second emission layer 322 may be formed to have a larger area (e.g., in a plan view) than the first emission layer 321. The CGL 340 may be formed to have a greater area (e.g., in a plan view) than at least the first emission layer 321.

Through the above structure, the contact hole 390CH is formed at a location spaced apart from the first emission layer 321 (e.g., in the -X direction) and the first electrode 310 so that the charge discharging structure from the CGL 340 may be precisely controlled via the contact hole 390CH. For example, the electric connection between the conductive layer 380 and the CGL 340 may be easily implemented through the contact hole 390CH.

In some embodiments, the above structure of FIG. 6 may be also applied to embodiments that are described later.

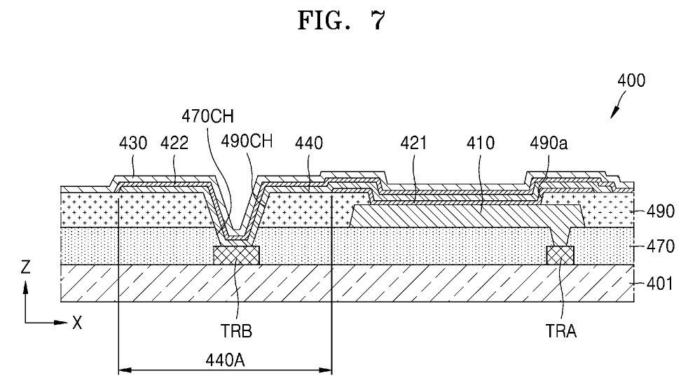

FIG. 7 is a schematic cross-sectional view of a display apparatus according to an embodiment of the present disclosure.

Referring to FIG. 7, in an embodiment a display apparatus 400 may include a substrate 401, a first electrode 410, a second electrode 430, a first emission layer 421, a second emission layer 422, and a CGL 440. Hereinafter, differences from an embodiment shown in FIG. 5 are described in detail for convenience of description.

For example, transistors TRA and TRB are different from the example of FIG. 5 and are described below.

One or more transistors TRB may be arranged to correspond to a contact hole 490CH of a pixel-defining layer 490. For example, the transistor TRB may be a thin film transistor (TFT).

In an embodiment, the transistor TRA may be arranged to be connected to the first electrode 410, and the transistor TRA may be a TFT.

The transistor TRB corresponding to the contact hole 490CH and the transistor TRA connected to the first electrode 410 may be separately driven. Through the above structure, a charge discharging process from the CGL 440 may be precisely performed at a desired point in time according to the control from the transistor TRB, without interfering with light emission from emission layers 421 and 422 between the first electrode 410 and the second electrode 430.

The CGL 440 may be arranged between the first emission layer 421 and the second emission layer 422 (e.g., in the Z direction). In some embodiments, the CGL 440 may include a charge connection region 440A that does not overlap the first emission layer 421 (e.g., in the Z direction) and overlaps the second emission layer 422 (e.g., in the Z direction).

The charge connection region 440A of the CGL 440 may be connected to (e.g., electrically connected thereto) the transistor TRB in at least one region. For example, the charge connection region 440A may be connected to (e.g., electrically connected to) the transistor TRB by being in direct contact with the transistor TRB. In an embodiment, the charge connection region 440A may correspond to at least the contact hole 490CH, for example, may overlap the contact hole 490CH (e.g., in the Z direction), and may be connected to (e.g., electrically connected thereto) the transistor TRB via the contact hole 490CH.

Since the charge connection region 440A is connected to (e.g., electrically connected thereto) the transistor TRB via the contact hole 490CH, the charge discharging structure from the CGL 440 may be easily implemented while reducing or preventing the interference of the first electrode 410 or the second electrode 430. For example, the charge connection region 440A of the CGL 440 may be connected to (e.g., electrically connected thereto) the transistor TRB via the contact hole 490CH, and thus, residual charges in the charge generation layer 440 may be easily discharged for a desired period of time at a desired point in time according to the control from the transistor TRB.

In an embodiment, one or more insulating layers 470 may be further arranged between the substrate 401 and the pixel-defining layer 490 (e.g., in the Z direction).

In some embodiments, a contact hole 470CH may be formed in the insulating layer 470, and the contact hole 470CH may be formed to correspond to and overlap the contact hole 490CH of the pixel-defining layer 490 (e.g., in the Z direction).

In some embodiments, the first electrode 410 may be arranged on (e.g., disposed directly thereon in the Z direction) the insulating layer 470, and as such, the convenience in forming the contact holes 490CH and 470CH for discharging charges from the CGL 440 and arranging the transistor TRB corresponding to the contact holes 490CH and 470CH may be increased.

The charges accumulated in the CGL 440 may be discharged through the charge connection region 440A of the CGL 440 in the display apparatus 400 of an embodiment, such as the region corresponding to the contact hole 490CH, and the charges may be selectively discharged through the transistor TRB at a desired point in time and for a desired period of time. The precision of the color emitted during driving the display apparatus 400 may be increased by precisely controlling the discharge of the charges from the CGL 440, and thus, the image quality characteristics may be increased.

In an embodiment, as shown in FIGS. 2 and 3, one or more layers along with the second emission layer 422 may be further included between the CGL 440 and the second electrode 430 (e.g., in the Z direction), such as one or more of an electron transport layer, a hole transport layer, and a hole injection layer. In some embodiments, one or more layers along with the first emission layer 421 may be further included between the CGL 440 and the first electrode 410 (e.g., in the Z direction), such as one or more of the electron transport layer, the hole transport layer, and the hole injection layer may be arranged.

In some embodiments, the example of the planar shape shown in FIG. 6 may be applied to an embodiment shown in FIG. 7.

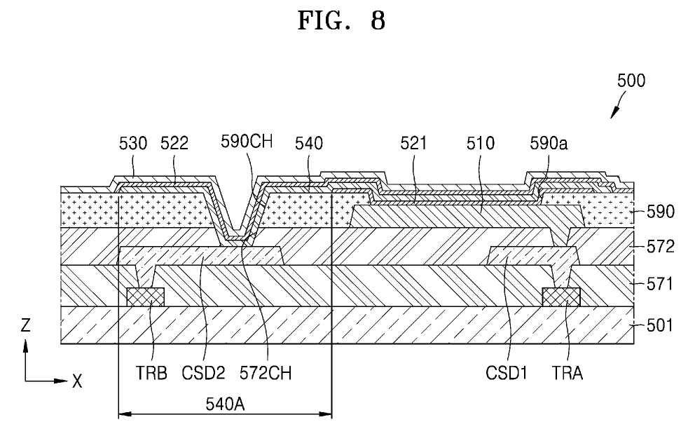

FIG. 8 is a schematic cross-sectional view of a display apparatus according to an embodiment of the present disclosure.

Referring to FIG. 8, in an embodiment a display apparatus 500 may include a substrate 501, a first electrode 510, a second electrode 530, a first emission layer 521, a second emission layer 522, and a CGL 540. Hereinafter, differences from an embodiment shown in FIG. 7 are described in detail for convenience of description.

Connection electrodes CSD1 and CSD2 are different from an embodiment of FIG. 7 and are described below.

One or more connection electrodes CSD2 are arranged to correspond to a contact hole 590CH of a pixel-defining layer 590, and the connection electrodes CSD2 may be connected to (e.g., electrically connected thereto) the transistor TRB. For example, the transistor TRB may be a TFT.

In an embodiment, the connection electrode CSD1 may be arranged to be connected to (e.g., electrically connected thereto) the first electrode 510, and the connection electrode CSD1 may be connected to (e.g., electrically connected thereto) the transistor TRA.

Locations of arranging the transistors TRA and TRB may be precisely selected at desired positions and arranged by arranging the connection electrodes CSD1 and CSD2.

In some embodiments, the transistor TRB and the transistor TRA are arranged to reduce interference, and thus, the characteristics of controlling individual driving may be increased. As such, the discharge of the charges from the CGL 540 may be precisely implemented at a desired point in time without interfering with the light emission from the first and second emission layers 521 and 522 between the first electrode 510 and the second electrode 530.

The CGL 540 may be arranged between the first emission layer 521 and the second emission layer 522 (e.g., in the Z direction). In some embodiments, the CGL 540 may include a charge connection region 540A that does not overlap the first emission layer 521 (e.g., in the Z direction) and overlaps the second emission layer 522 (e.g., in the Z direction).

The charge connection region 540A of the CGL 540 may be connected to (e.g. electrically connected thereto) the transistor TRB in at least one region, for example, may be electrically connected to the transistor TRB via the connection electrode CSD2. In an embodiment, the charge connection region 540A may correspond to at least the contact hole 590CH, for example, may overlap the contact hole 590CH (e.g., in the Z direction), and may be connected to (e.g., electrically connected thereto) the connection electrode CSD2 in the contact hole 590CH and may be connected to the transistor TRB via the connection electrode CSD2.

Since the charge connection region 540A is electrically connected to the transistor TRB via the contact hole 590CH, the charge discharging structure from the CGL 540 may be easily implemented while reducing or preventing the interference of the first electrode 510 or the second electrode 530. For example, the charge connection region 540A of the CGL 540 may be connected to (e.g. electrically connected thereto) the transistor TRB via the contact hole 590CH, and thus, residual charges in the CGL 540 may be easily discharged for a desired period of time at a desired point in time according to the control from the transistor TRB.

In an embodiment, one or more insulating layers may be further arranged between the substrate 501 and the pixel-defining layer 590 (e.g., in the Z direction).

For example, in an embodiment a first insulating layer 571 and a second insulating layer 572 may be arranged on the substrate 501.

In an embodiment, the transistors TRA and TRB are arranged on (e.g., directly thereon) the substrate 501 and the first insulating layer 571, and the connection electrodes CSD1 and CSD2 may be arranged between the first insulating layer 571 and the second insulating layer 572.

In some embodiments, a contact hole 572CH may be formed in the second insulating layer 572, and the contact hole 572CH may be formed to correspond to and overlap (e.g., in the Z direction) the contact hole 590CH of the pixel-defining layer 590.

In some embodiments, the first electrode 510 may be arranged between the second insulating layer 572 and the pixel-defining layer 590, and as such, convenience in forming the contact holes 590CH and 572CH for discharging charges from the CGL 540 and arranging the transistor TRB corresponding to the contact holes 590CH and 572CH may be increased.

The charges accumulated in the CGL 540 may be discharged through the charge connection region 540A of the CGL 540 in the display apparatus 500 of an embodiment, such as the region corresponding to the contact hole 590CH, and the charges may be selectively discharged through the transistor TRB at a desired point in time and for a desired period of time. The precision of the color emitted during driving the display apparatus 500 may be increased by precisely controlling the discharging of the charges from the CGL 540, and thus, the image quality characteristics may be increased.

In an embodiment, as shown in FIGS. 2 and 3, one or more layers along with the second emission layer 522 may be further included between the CGL 540 and the second electrode 530 (e.g., in the Z direction), for example, one or more of an electron transport layer, a hole transport layer, and a hole injection layer may be arranged. In some embodiments, one or more layers along with the first emission layer 521 may be further included between the CGL 540 and the first electrode 510 (e.g., in the Z direction), for example, one or more of the electron transport layer, the hole transport layer, and the hole injection layer may be arranged.

In some embodiments, the example of the planar shape shown in FIG. 6 may be applied to an embodiment shown in FIG. 8.

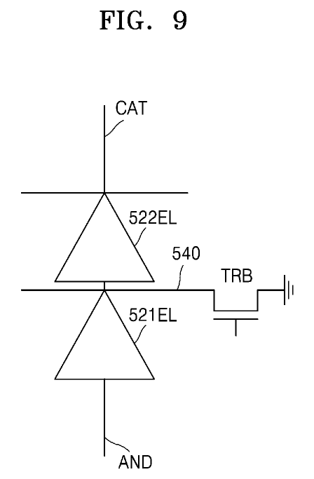

FIG. 9 is a schematic diagram illustrating examples of the CGL and the transistor in the display apparatus of FIG. 8.

Referring to FIG. 9, two organic light-emitting devices are shown. For example, a first organic light-emitting device 521EL and a second organic light-emitting device 522EL are shown. In an embodiment, the first organic light-emitting device 521EL may include the first electrode 510 (see FIG. 8), the first emission layer 521 (see FIG. 8), and the CGL 540, and the second organic light-emitting device 522EL may include, for example, the CGL 540, the second emission layer 522 (see FIG. 8), and the second electrode 530 (see FIG. 8). In some embodiments, the first electrode 510 may be connected to an anode AND and the second electrode 530 may be connected to a cathode CAT.

The CGL 540 may be electrically connected to the transistor TRB, for example, via the connection electrode CSD2 (see FIG. 8).

The charges abnormally remaining in the CGL 540 may be removed via the transistor TRB. For example, the charges remaining in the charge generation layer 540 may be discharged by controlling the transistor TRB for a desired period of time at a desired point in time, and in more detail, a process of discharging or removing the charges from the CGL 540 may be performed at a time when the light emission from the first organic light-emitting device 521EL and the second organic light-emitting device 522EL is not affected.

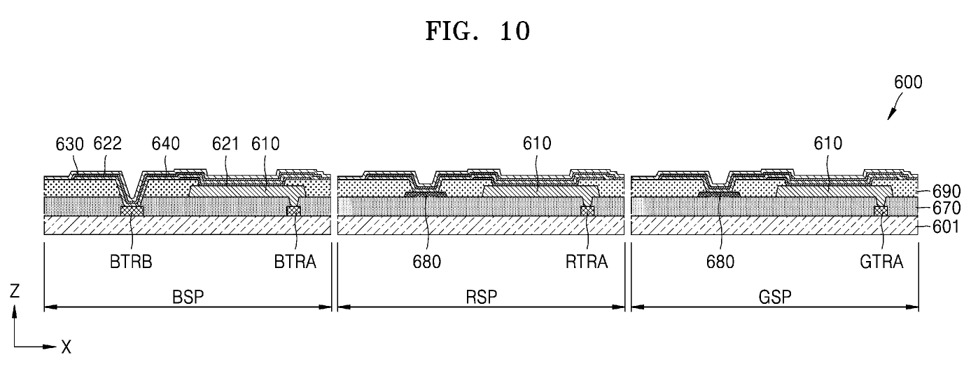

FIG. 10 is a schematic cross-sectional view of a display apparatus according to an embodiment of the present disclosure.

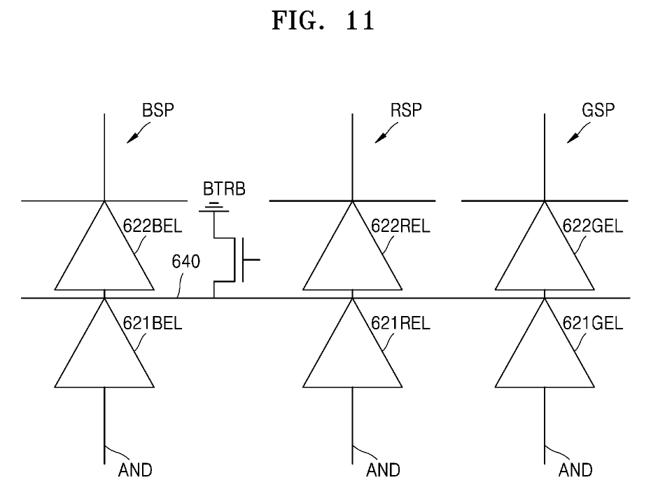

FIG. 11 is a schematic diagram illustrating examples of a CGL and a transistor in the display apparatus of FIG. 10.

Referring to FIG. 10, in an embodiment a display apparatus 600 may include a substrate 601, a first electrode 610, a second electrode 630, a first emission layer 621, a second emission layer 622, a CGL 640, and a conductive layer 680. Hereinafter, differences from an embodiment shown in FIG. 8 are described in detail for convenience of description.

FIG. 10 shows a structure including a plurality of sub-pixels as compared with FIG. 8.

For example, in an embodiment the display apparatus 600 may include at least three sub-pixels BSP, RSP, and GSP.

In an embodiment, the three sub-pixels BSP, RSP, and GSP may be sub-pixels implementing the same color. However, embodiments of the present disclosure are not necessarily limited thereto. For example, in an embodiment the plurality of sub-pixels may include at least one sub-pixel implementing a different color from the other sub-pixels.

In an embodiment, the three sub-pixels BSP, RSP, and GSP may implement different colors from one another, such as blue, red, and green light.

In some embodiments, the first emission layer 621 and the second emission layer 622 may be selectively controlled to correspond to the colors implemented by the three sub-pixels BSP, RSP, and GSP. In an embodiment, the sub-pixel BSP may include the first emission layer 621 and the second emission layer 622 that are blue-based, the sub-pixel RSP may include the first emission layer 621 and the second emission layer 622 that are red-based, and the sub-pixel GSP may include the first emission layer 621 and the second emission layer 622 that are green-based.

In some embodiments, at least one of the three sub-pixels BSP, RSP, and GSP may include a transistor BTRB electrically connected to the CGL 640.

In some embodiments, the transistor BTRB may be electrically connected to the conductive layer 680 of another pixel. As such, the three sub-pixels may be electrically and commonly connected to the CGL 640 corresponding to the three sub-pixels BSP, RSP, and GSP via the transistor BTRB.

In some embodiments, in the three sub-pixels BSP, RSP, and GSP, transistors BTRA, RTRA, and GTRA electrically connected to the first electrode 610 may be respectively arranged.

In some embodiments, one or more connection electrodes may be arranged to be connected to the transistors as shown in the display apparatus 500 of FIG. 8 described above.

The CGL 640 may be arranged between the first emission layer 621 and the second emission layer 622 (e.g., in the Z direction). In some embodiments, the CGL 640 may include a charge connection region that does not overlap the first emission layer 621 (e.g., in the Z direction) and overlaps the second emission layer 622 (e.g., in the Z direction).

The CGL 640 may be arranged to be distinguished for each sub-pixel.

In an embodiment, the CGL 640 may extend to correspond to the plurality of sub-pixels.

In an embodiment, one or more insulating layers 670 may be further arranged between the substrate 601 and the pixel-defining layer 690 (e.g., in the Z direction).

In an embodiment, as shown in FIGS. 2 and 3, one or more layers along with the second emission layer 622 may be further included between the CGL 640 and the second electrode 630 (e.g., in the Z direction), such as one or more of an electron transport layer, a hole transport layer, and a hole injection layer. In some embodiments, one or more layers along with the first emission layer 621 may be further included between the CGL 640 and the first electrode 610 (e.g., in the Z direction), such as one or more of the electron transport layer, the hole transport layer, and the hole injection layer.

In some embodiments, the example of the planar shape shown in FIG. 6 may be applied to an embodiment shown in FIG. 10.

FIG. 11 is a schematic diagram illustrating examples of the CGL and the transistor in the display apparatus of FIG. 10.

Referring to FIG. 11, in an embodiment the plurality of sub-pixels includes three sub-pixels BSP, RSP, and GSP, and two organic light-emitting devices are shown in each sub-pixel. For example, first organic light-emitting devices 621BEL, 621REL, and 621GEL and second organic light-emitting devices 622BEL, 622REL, and 622GEL are shown, respectively. The first organic light-emitting devices 621BEL, 621REL, and 621GEL may each include, for example, the first electrode 610 (see FIG. 10), the first emission layer 621 (see FIG. 10), and the CGL 640, and the second organic light-emitting devices 622BEL, 622REL, and 622GEL may each include, for example, the CGL 640, the second emission layer 622 (see FIG. 10), and the second electrode 630 (see FIG. 10). In some embodiments, the first electrode 610 may be connected to (e.g., electrically connected thereto) an anode AND and the second electrode 630 may be connected to (e.g., electrically connected thereto) a cathode CAT.

The CGL 640 may be electrically connected to the transistor BTRB.

With respect to the CGL 640 corresponding to the plurality of sub-pixels, such as three sub-pixels BSP, RSP, and GSP, the charges abnormally remaining in the CGL 640 may be removed through the transistor BTRB. For example, the charges remaining in the CGL 640 may be discharged to be removed by controlling the transistor BTRB for a desired period of time at a desired point in time.

In an embodiment, a plurality of transistors may be arranged so as to correspond respectively to the three sub-pixels BSP, RSP, and GSP, and the plurality of transistors may be independently controlled. In some embodiments, the charge discharging process with respect to the CGL 640 may be easily controlled for each sub-pixel as necessary.

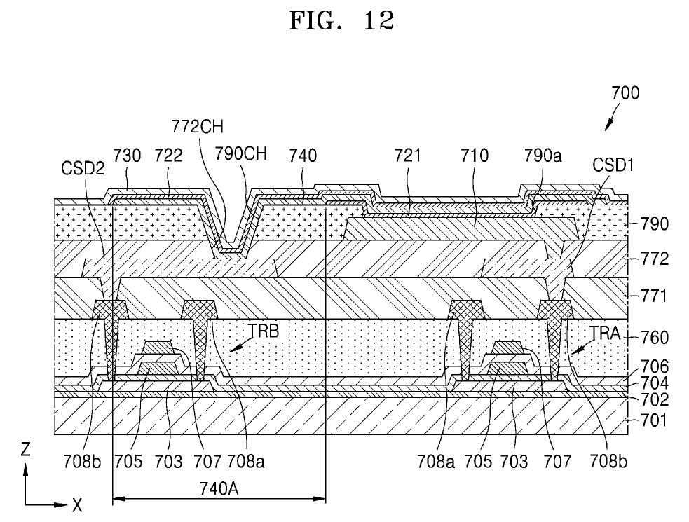

FIG. 12 is a schematic cross-sectional view of a display apparatus 700 according to an embodiment of the present disclosure.

Referring to FIG. 12, in an embodiment a display apparatus 700 may include a substrate 701, a first electrode 710, a second electrode 730, a first emission layer 721, a second emission layer 722, a CGL 740, and a transistor TRB. Hereinafter, differences from the above embodiment are described in detail for convenience of description.

The display apparatus 700 of the embodiment is similar to the display apparatus 500 of an embodiment shown in FIG. 8, except for a detailed shape of the transistor, and thus, the difference is described in detail below.

Transistors TRA and TRB may be arranged on the substrate 701. The transistors TRA and TRB may have various shapes, for example, may include TFTs. The transistors TRA and TRB may each include an active layer 703, a gate electrode 705, a source 708a, and a drain 708b. According to an embodiment, the active layer 703, the gate electrode 705, the source 708a, and the drain 708b in each of the transistors TRA and TRB are arranged in the same layer, but may be arranged in different layers from each other as well. In some embodiments, hereinafter, an example in which the TFT is a top gate type in which the active layer 703, the gate electrode 705, the source 708a, and the drain 708b are sequentially formed.

However, embodiments of the present disclosure are not necessarily limited thereto, and TFTs of various types such as a bottom gate type, etc. may be adopted.

In an embodiment, one or more buffer layers 702 may be arranged on the substrate 701.

The buffer layer 702 may be arranged on the substrate 701 (e.g., disposed directly thereon in the Z direction). The buffer layer 702 may reduce or prevent dispersion of impurities into the TFT that is to be arranged on the buffer layer.

The buffer layer 702 may include various materials, such as an inorganic material. In an embodiment, a silicon-based material may be included. In an embodiment, the buffer layer 702 may include at least one of silicon nitride (SiNx), silicon oxide (SiOx), and silicon oxynitride (SiOxNy).

In an embodiment, the buffer layer 702 may include an oxide material, such as at least one of metal oxides such as aluminum oxide (AlOx).

In an embodiment, the buffer layer 702 may include multiple layers, such as at least dual layers.

The active layer 703 is formed on the buffer layer 702 (e.g., disposed directly thereon in the Z direction). The active layer 703 may include a semiconductor material, such as amorphous silicon or polycrystalline silicon. However, embodiments of the present disclosure are not necessarily limited to the above example, and the active layer 703 may include various materials. In an embodiment, the active layer 703 may include an organic semiconductor material.

In an embodiment, the active layer 703 may include an oxide semiconductor material. For example, the active layer 703 may include oxide of a material selected from Group 12, 13, and 14 metal elements such as zinc (Zn), indium (In), gallium (Ga), tin (Sn), cadmium (Cd), germanium (Ge), or hafnium (Hf), and a combination thereof.

The gate insulating layer 704 is formed on (e.g., disposed directly thereon) the active layer 703. In an embodiment, the gate insulating layer 704 may include a multi-layered or single-layered structure including an inorganic material such as silicon oxide and/or silicon nitride, etc. The gate insulating layer 704 may insulate the active layer 703 and the gate electrode 705 from each other.

The gate electrode 705 is formed on the gate insulating layer 704 (e.g., disposed directly thereon in the Z direction). In an embodiment, the gate electrode 705 may be connected to a gate line transferring one or more electrical signals.

In an embodiment, the gate electrode 705 may include a low-resistive metal material, for example, multiple layers or single layer including a conductive material including molybdenum (Mo), aluminum (Al), copper (Cu), titanium (Ti), etc.

An interlayer insulating layer 760 is formed on (e.g., disposed directly thereon) the gate electrode 705. The interlayer insulating layer 760 may insulate the source 708a and the drain 708b from the gate electrode 705.

In an embodiment, an upper electrode 707 may be arranged to overlap the gate electrode 705 (e.g., in the Z direction), and an intermediate insulating layer 706 may be arranged between the gate electrode 705 and the upper electrode 707 (e.g., in the Z direction).

The source 708a and the drain 708b are formed on the interlayer insulating layer 760 (e.g., disposed directly thereon in the Z direction). The source 708a and the drain 708b may be formed to have a single layer or a plurality of layers including a material having excellent conductivity.

The source 708a and the drain 708b may be formed to come into direct contact with the regions of the active layer 703.

The source 708a or the drain 708b, for example, the drain 708b, may be connected to the connection electrode CSD1 or CSD2.

In an embodiment, one or more insulating layers may be further arranged. For example, the first insulating layer 771 and the second insulating layer 772 may be arranged on the transistors TRA and TRB, and may be arranged between the interlayer insulating layer 760 and the pixel-defining layer 790 (e.g., in the Z direction).

In some embodiments, a contact hole 772CH may be formed in the second insulating layer 772, and the contact hole 772CH may be formed to correspond to and overlap the contact hole 790CH of the pixel-defining layer 790 (e.g., in the Z direction).

The CGL 740 may be arranged between the first emission layer 721 and the second emission layer 722 (e.g., in the Z direction). In some embodiments, the CGL 740 may include a charge connection region 740A that does not overlap the first emission layer 721 (e.g., in the Z direction) and overlaps the second emission layer 722 (e.g., in the Z direction).

Other components are the same as the above descriptions of the display apparatus 500 provided above with reference to FIG. 8, and detailed descriptions are omitted for economy of description.

In an embodiment, as shown in FIGS. 2 and 3, one or more layers along with the second emission layer 722 may be further included between the CGL 740 and the second electrode 730 (e.g., in the Z direction), such as one or more of an electron transport layer, a hole transport layer, and a hole injection layer. In some embodiments, one or more layers along with the first emission layer 721 may be further included between the CGL 740 and the first electrode 710 (e.g., in the Z direction), for example, one or more of the electron transport layer, the hole transport layer, and the hole injection layer.

In some embodiments, the example of the planar shape shown in an embodiment of FIG. 6 may be applied to an embodiment shown in FIG. 12.

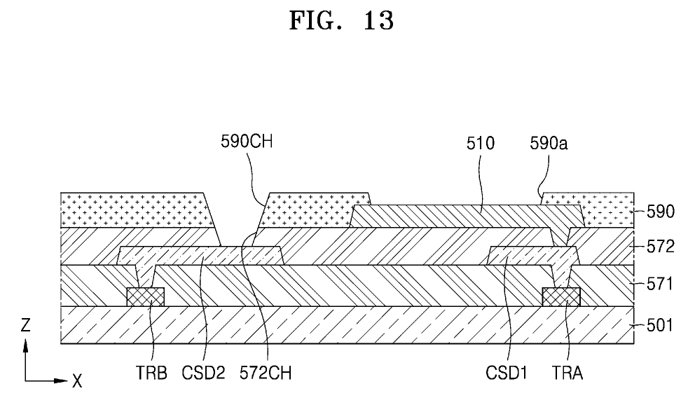

FIGS. 13 to 17 are diagrams schematically illustrating a method of manufacturing the display apparatus, according to embodiments of the present disclosure.

For example, FIGS. 13 to 17 may illustrate an example of method of manufacturing the display apparatus 500 of FIG. 8.

In some embodiments, the method of FIGS. 13 to 17 may be applied as is or modified within a similar range, and then, may be applied to the display apparatus described above or a display apparatus that is described later.

Referring to FIG. 13, the transistors TRA and TRB are arranged on the substrate 501, and the connection electrodes CSD1 and CSD2 are arranged thereabove.

In some embodiments, the first insulating layer 571 and the second insulating layer 572 are arranged on the substrate 501, and then, the pixel-defining layer 590 may be arranged on the second insulating layer 572 (e.g., disposed directly thereon in the Z direction).

The contact hole 572CH may be formed in the second insulating layer 572, and the contact hole 572CH may be formed to correspond to and overlap (e.g., in the Z direction) the contact hole 590CH of the pixel-defining layer 590.

The opening 590a of the pixel-defining layer 590 may be formed to be spaced apart from the contact hole 590CH in a plan view (e.g., in the X direction) and to overlap the first electrode 510 in a plan view (e.g., in the Z direction).

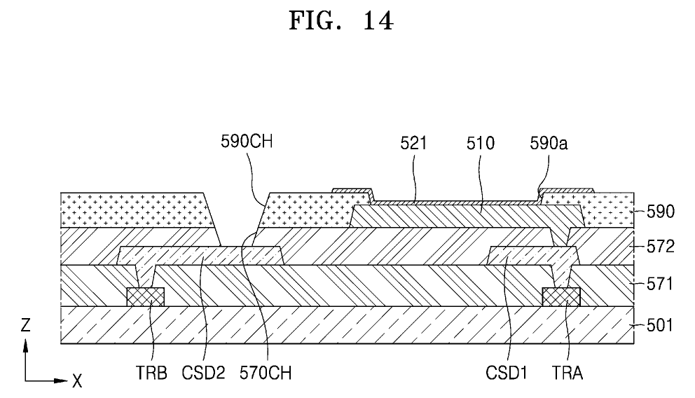

Referring to FIG. 14, the first emission layer 521 is formed to overlap the first electrode 510 (e.g., in the Z direction). The first emission layer 521 may be formed so as not to correspond to and overlap the contact hole 590CH (e.g., in the Z direction).

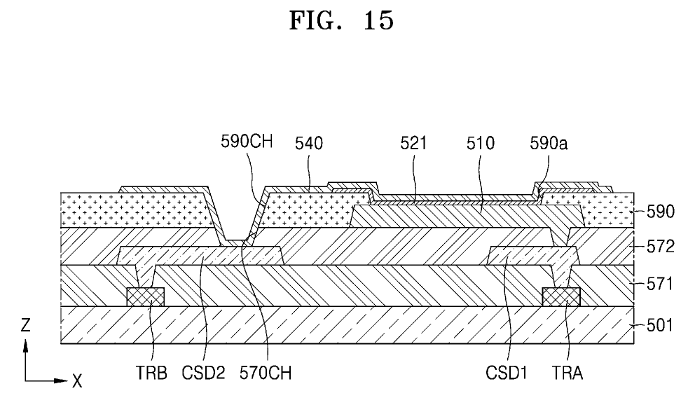

Referring to FIG. 15, the CGL 540 is arranged on the first emission layer 521. For example, the CGL 540 may be formed to extend past at least one edge of the first emission layer 521 to a portion of the CGL 540 that does not overlap the first emission layer 521. In an embodiment, the CGL 540 may be formed to have a greater area (e.g., in a plan view) than the first emission layer 521. In some embodiments, the CGL 540 may be arranged to correspond to the contact hole 590CG and may be electrically connected to the connection electrode CSD2, such as by directly contacting the connection electrode CSD2.

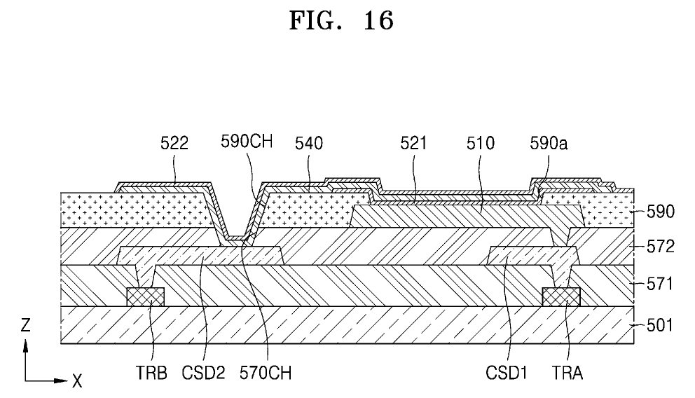

Referring to FIG. 16, the second emission layer 522 may be formed on (e.g., formed directly thereon) the CGL 540. The second emission layer 522 may be formed to pass by at least one edge of the first emission layer 521, and may be formed to have a greater area (e.g., in a plan view) than the first emission layer 521. In some embodiments, the second emission layer 522 may be arranged to correspond to and overlap the contact hole 590CH (e.g., in the Z direction).

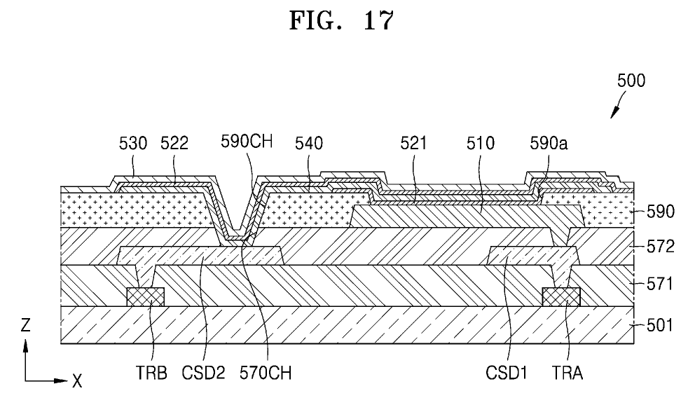

Referring to FIG. 17, the second electrode 530 may be formed on (e.g., formed directly thereon) the second emission layer 522.

In a manufacturing method according to an embodiment of the present disclosure, the display apparatus 500 having a structure in which the first emission layer 521 and the second emission layer 522 overlap each other (e.g., in the Z direction), such as a tandem structure, may be easily manufactured. In some embodiments, the display apparatus 500 capable of precisely controlling the discharging or removal of the charges remaining in the CGL 540 when the charges abnormally remain in the CGL 540 may be easily manufactured.

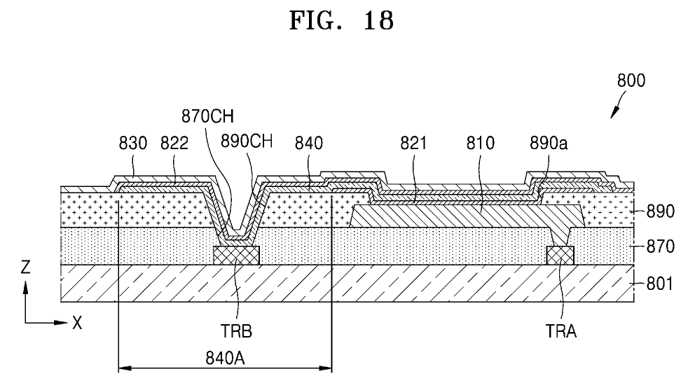

FIG. 18 is a schematic cross-sectional view of a display apparatus according to an embodiment of the present disclosure.

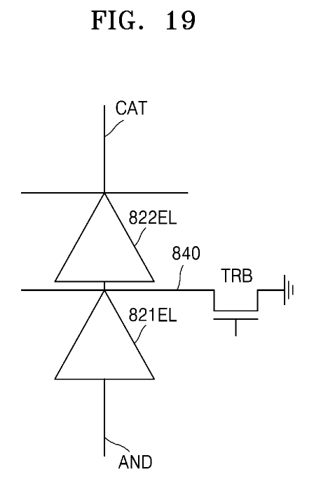

FIG. 19 is a schematic diagram illustrating examples of an intermediate electrode and a transistor in the display apparatus of FIG. 18.

Referring to FIG. 18, in an embodiment a display apparatus 800 may include a substrate 801, a first electrode 810, a second electrode 830, a first emission layer 821, a second emission layer 822, and an intermediate electrode 840. Hereinafter, differences from an embodiment shown in FIG. 17 are described in detail for convenience of description.

The substrate 801 may include various materials. In an embodiment, the substrate 801 may include glass, metal, an organic material, or other materials, and may be modified and applied within a range substantially the same as or similar to that provided in an embodiment shown in FIG. 17. Thus, detailed descriptions are omitted.

The first electrode 810 may have various shapes, such as may be patterned in an island shape. The first electrode 810 may be modified and applied within the range that is substantially the same as or similar to the descriptions provided in an embodiment shown in FIG. 17, and thus detailed descriptions are omitted.

The second electrode 830 may be arranged to face the first electrode 810. The second electrode 830 may include various conductive materials. For example, the second electrode 830 may be modified and applied within the range that is substantially the same as or similar to the descriptions provided in an embodiment shown in FIG. 17, and thus detailed descriptions are omitted.

The first emission layer 821 may be arranged between the first electrode 810 and the second electrode 830 (e.g., in the Z direction). In an embodiment, the first emission layer 821 may include, for example, an organic emission layer, such as a low-molecular weight organic material or a high-molecular weight organic material.

In some embodiments, the first emission layer 821 may be arranged so as not to correspond to and overlap (e.g., in the Z direction) the contact hole 890CH that is described later.

The pixel-defining layer 890 may be on (e.g., disposed directly thereon) the first electrode 810.

The pixel-defining layer 890 is arranged so as not to cover a certain region of the first electrode 810, and the first emission layer 821 may be arranged so as to overlap the region of the first electrode 810 (e.g., in the Z direction), which is not covered by the pixel-defining layer 890, such as an opening 890a of the pixel-defining layer 890.

The pixel-defining layer 890 may include various insulating materials. For example, in an embodiment the pixel-defining layer 890 may include an organic material, such as one or more organic insulating materials selected from the group consisting of polyimide, polyamide, acrylic resin, benzocyclobutene, and phenol resin and formed by a method such as spin coating, etc.

In some embodiments, the pixel-defining layer 890 may include the contact hole 890CH having a depth corresponding to at least a partial thickness or total thickness of the pixel-defining layer. The contact hole 890CH may be spaced apart from the opening 890a in a plan view (e.g., in the -X direction) and may not overlap the opening 890a in a plan view (e.g., in the Z direction).

One or more transistors TRB may be arranged to correspond to the contact hole 890CH of the pixel-defining layer 890. For example, the transistor TRB may be a TFT.

In an embodiment, the transistor TRA may be arranged to be connected to (e.g., electrically connected thereto) the first electrode 810, and the transistor TRA may include a TFT.

The transistor TRB corresponding to the contact hole 890CH and the transistor TRA connected to the first electrode 810 may be separately driven. As such, the discharge of the charges from the intermediate electrode 840 may be precisely implemented at a desired point in time without interfering with the light emission from the first and second emission layers 821 and 822 between the first electrode 810 and the second electrode 830.

The second emission layer 822 may be arranged between the first electrode 810 and the second electrode 830 (e.g., in the Z direction).

In some embodiments, the second emission layer 822 may be arranged so as to at least partially overlap the first emission layer 821 (e.g., in the Z direction).

For example, the display apparatus 800 of an embodiment has a tandem-type structure in which two or more emission layers overlap each other, for example, the first emission layer 821 and the second emission layer 822 overlap each other (e.g., in the Z direction).

The second emission layer 822 may be arranged so that the second emission layer 822 may not overlap the first emission layer 821 (e.g., in the Z direction) in a region. For example, the second emission layer 822 may extend past at least an edge of the first emission layer 821 and may include a region that does not overlap the first emission layer 82 (e.g., in a thickness direction of the substrate 801, such as the Z direction).

In an embodiment, the second emission layer 822 may include, for example, an organic emission layer, such as a low-molecular weight organic material or a high-molecular organic material.

Types of the first emission layer 821 and the second emission layer 822 may be various. For example, in an embodiment the color emitted from the second emission layer 822 may be different from the color emitted from the first emission layer 821.

In some embodiments, the first emission layer 821 and the second emission layer 822 may implement light of a same color base with different luminance from each other. In an embodiment, the first emission layer 821 may implement deep blue light and the second emission layer 822 may implement light blue light.

In some embodiments, the first emission layer 821 may implement deep red light and the second emission layer 822 may implement light red light. In an embodiment, the first emission layer 821 may implement deep green light and the second emission layer 822 may implement light green light.

In some embodiments, the second emission layer 822 may be arranged to correspond to and overlap the contact hole 890CH (e.g., in the Z direction).

The intermediate electrode 840 may be arranged between the first emission layer 821 and the second emission layer 822 (e.g., in the Z direction). In some embodiments, the intermediate electrode 840 may include a connection region 840A that does not overlap the first emission layer 821 (e.g., in the Z direction) and overlaps the second emission layer 822 (e.g., in the Z direction).

The intermediate electrode 840 may be arranged between the first emission layer 821 and the second emission layer 822 (e.g., in the Z direction) and control selective light emission from the first emission layer 821 and the second emission layer 822.

In an embodiment, two devices may be implemented based on the intermediate electrode 840. For example, the first electrode 810, the first emission layer 821, and the intermediate electrode 840 may be implemented as one device (e.g., a first light-emitting device), and at this time, the first electrode 810 and the intermediate electrode 840 may function as relative electrodes with each other. For example, the first electrode 810 may function as an anode and the intermediate electrode 840 may function as a cathode.

In some embodiments, the second electrode 830, the second emission layer 822, and the intermediate electrode 840 may be implemented as one device (e.g., a second light-emitting device), and in this embodiment the second electrode 830 and the intermediate electrode 840 may function as relative electrodes with each other. For example, the second electrode 830 may function as a cathode and the intermediate electrode 840 may function as an anode.

In some embodiments, two light-emitting devices may be selectively driven. For example, when the first light-emitting device including the first emission layer 821 is driven, the second light-emitting device including the second emission layer 822 may not be driven. On the contrary, when the second light-emitting device including the second emission layer 822 is driven, the first light-emitting device including the first emission layer 821 may not be driven.

In some embodiments, an electric field may be controlled so that the intermediate electrode 840 may function as an anode or a cathode as necessary, for example, the applied electric field may be controlled via the transistor TRB.

Precise light emission from the first emission layer 821 and the second emission layer 822 may be controlled by using the intermediate electrode 840, for example, selective control may be easily performed. As such, color coordinates of the light implemented by the display apparatus 800 may be precisely controlled. In an embodiment, various color-reproduction range may be secured, as described above, by allowing the first emission layer 821 and the second emission layer 822 to reproduce the light of the same color base with different luminance, such as deep blue and light blue, and in color combination (e.g., white implementation), power consumption of the display apparatus may be easily reduced by implementing light blue, light green, and light red.

The connection region 840A of the intermediate electrode 840 may include a region that does not overlap at least the first emission layer 821 (e.g., in a thickness direction of the substrate 801, such as the Z direction) and overlaps the second emission layer 822 (e.g., in a thickness direction of the substrate 801, such as the Z direction).

The intermediate electrode 840 is electrically connected to the transistor TRB via the connection region 840A of the intermediate electrode 840, and may reduce or prevent interference with the transistor TRA connected to the first electrode 810.

The connection region 840A of the intermediate electrode 840 may be connected to (e.g., electrically connected thereto) the transistor TRB via at least a region. For example, the connection region 840A may be connected to (e.g., electrically connected thereto) the transistor TRB by directly contacting the transistor TRB. In an embodiment, the connection region 840A may correspond to at least the contact hole 890CH, for example, may overlap the contact hole 890CH (e.g., in the Z direction), and may be connected to (e.g., electrically connected thereto) the transistor TRB via the contact hole 890CH.

Since the connection region 840A is connected to (e.g., electrically connected thereto) the transistor TRB via the contact hole 890CH, the arrangement structure of the intermediate electrode 840 may be precisely controlled while reducing or preventing interference with the first electrode 810 or the second electrode 830. For example, the connection region 840A of the intermediate electrode 840 is connected to (e.g., electrically connected thereto) the transistor TRB via the contact hole 890CH, and the electric field applied to the intermediate electrode 840 may be precisely controlled for a desired period of time at a desired point in time through the control of the transistor TRB.

In an embodiment, one or more insulating layers 870 may be further arranged between the substrate 801 and the pixel-defining layer 890 (e.g., in the Z direction).

In some embodiments, a contact hole 870CH may be formed in the insulating layer 870, and the contact hole 870CH may be formed to correspond to and overlap the contact hole 890CH of the pixel-defining layer 890 (e.g., in the Z direction).

In some embodiments, the first electrode 810 may be arranged on (e.g., disposed directly thereon) the insulating layer 870, and as such, the convenience in forming the contact holes 890CH and 870CH for discharging charges from the intermediate electrode 840 and arranging the transistor TRB corresponding to the contact holes 890CH and 870CH may be increased.

In the display apparatus 800 of an embodiment, the connection region 840A of the intermediate electrode 840, such as the region corresponding to the contact hole 890CH, is electrically connected to the transistor TRB, and the electric field applied to the intermediate electrode 840 may be precisely controlled at a desired point in time and for a desired period of time through the control of the transistor TRB. As such, the image quality characteristics of the display apparatus 800 may be increased and the power consumption may be reduced.

In an embodiment, as shown in FIGS. 2 and 3, one or more layers along with the second emission layer 822 may be further included between the intermediate electrode 840 and the second electrode 830 (e.g., in the Z direction), such as one or more of an electron transport layer, a hole transport layer, and a hole injection layer. In some embodiments, one or more layers along with the first emission layer 821 may be further included between the intermediate electrode 840 and the first electrode 810 (e.g., in the Z direction), such as one or more of the electron transport layer, the hole transport layer, and the hole injection layer may be arranged.

In some embodiments, the example of the planar shape shown in FIG. 6 may be applied to an embodiment shown in FIG. 18.

In some embodiments, the display apparatus 800 may selectively adopt the connection electrode described above with reference to FIG. 7.

In some embodiments, the display apparatus 800 may selectively adopt the detailed structure of the TFT described above with reference to FIG. 12.

In some embodiments, the display apparatus 800 may selectively adopt the detailed structure of a plurality of sub-pixels described above with reference to FIG. 10. In this embodiment, the display apparatus 800 connects (e.g., electrically connects) the transistor TRB to the intermediate electrode 840 in each of the plurality of sub-pixels, so as to individually control each sub-pixel. In an embodiment, a common transistor TRB may be connected to the intermediate electrode 840 corresponding to the plurality of sub-pixels according to design conditions of the first electrode and the second electrode.

FIG. 19 is a schematic diagram illustrating examples of the intermediate electrode and the transistor in the display apparatus of FIG. 18.

Referring to FIG. 19, two organic light-emitting devices are shown. A first organic light-emitting device 821EL and a second organic light-emitting device 822EL are shown. In an embodiment, the first organic light-emitting device 821EL may include the first electrode 810 (see FIG. 18), the first emission layer 821 (see FIG. 18), and the intermediate electrode 840, and the second organic light-emitting device 822EL may include, for example, the intermediate electrode 840, the second emission layer 822 (see FIG. 18), and the second electrode 830 (see FIG. 18). In some embodiments, the first electrode 810 may be connected to an anode AND and the second electrode 830 may be connected to a cathode CAT.

The intermediate electrode 840 may be electrically connected to the transistor TRB.

The electric field applied to the intermediate electrode 840 may be precisely controlled via the transistor TRB.

As such, individual driving for each of the first organic light-emitting device 821EL and the second organic light-emitting device 822EL may be precisely controlled.

In some embodiments, at least one of the display apparatuses described in the above embodiments may be applied to an electronic apparatus (e.g., an electronic device).

For example, the electronic apparatus (e.g., the electronic device) may include one or more display apparatuses and other components.

For example, the electronic apparatus (e.g., the electronic device) of an embodiment may include at least one of the above-described display apparatuses, and additionally, may include one or more of a processor, a memory, an input module, a power module, an embedded module, and an external module.

The processor may execute software to control at least one other component (e.g., a hardware or software component) of the electronic apparatus connected with the processor and perform data processing or computations. According to an embodiment, as at least part of the data processing or computation, the processor may load a command or data received from another component (e.g., an input module, a sensor module, or a communication module) in volatile memory, process the command or the data stored in the volatile memory, and store resulting data in non-volatile memory.

In an embodiment, the processor may include a main processor and an auxiliary processor. The main processor may include at least one of a central processing unit (CPU) and an application processor (AP). The main processor may further include at least one of a graphic processing unit (GPU), a communication processor (CP), and an image signal processor (ISP). The main processor may further include a neural processing unit (NPU). The NPU may be a processor specialized in processing of an artificial intelligence model, and the artificial intelligence model may be generated through machine learning. The artificial intelligence model may include a plurality of artificial neural network layers. The artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination of at least two thereof, but is not limited to the examples described above. The artificial intelligence model may additionally or alternatively include a software structure in addition to a hardware structure. At least two of the processing units and the processors described above may be implemented as one integrated component (e.g., a single chip), or may be implemented as independent components (e.g., a plurality of chips), respectively.

The auxiliary processor may include a controller, and the controller may include an interface conversion circuit and a timing control circuit. The controller receives an image signal from the main processor, converts a data format of the image signal to meet interface specifications with the display apparatus, and outputs image data. The controller may output various control signals for driving the display apparatus.

In an embodiment, the auxiliary processor may further include a controller, a data converting circuit, a gamma correction circuit, a rendering circuit, etc. The data converting circuit may receive the image data from the controller and may compensate the image data such that the image is displayed with a desired luminance according to characteristics of the electronic apparatus or a user setting or may convert the image data to reduce a power consumption or compensate for afterimages. The gamma correction circuit may convert the image data or a gamma reference voltage such that the image displayed on the electronic apparatus has desired gamma characteristics. The rendering circuit may receive the image data from the controller and may render the image data based on a pixel arrangement of the display apparatus applied to the electronic apparatus.

The input module may receive commands or data used to the components of the electronic apparatus (e.g., processor, sensor module, or sound output module) from the outside of the electronic apparatus (e.g., the user or the external electronic apparatus).

The input module may include a first input module for receiving commands or data from the user and a second input module for receiving commands or data from the external electronic apparatus. The first input module may include a microphone, a mouse, a keyboard, a key (e.g., a button) or a pen (e.g., a passive pen or an active pen). The second input module may support a designated protocol capable of connecting to the external electronic apparatus by a wire (e.g., cable) or wirelessly. According to an embodiment, the second input module may include a high-definition multimedia interface (HDMI), a universal serial bus (USB) interface, an SD card interface, or an audio interface. The second input module may include a connector physically connected to the external electronic apparatus, for example, an HDMI connector, a USB connector, an SD card connector, or an audio connector (e.g., a headphone connector).

In some embodiments, the display apparatus may further include a light emission driver. The light emission driver outputs a light emission control signal that is necessary for light emission from the display apparatus in response to a control signal received from the controller. The light emission driver may be formed independently from a scan driver or integrated with the scan driver.

In some embodiments, the display apparatus may include the scan driver receiving a control signal from the controller and outputting scan signals in response to the control signal.

In some embodiments, the display apparatus may include a data driver receiving a control signal from the controller and converting and outputting the image data into an analog voltage in response to the control signal.

The electronic apparatus may further include an embedded module and an external module. The embedded module may include a sensor module, an antenna module, and a sound output module. The external module may include a camera module, a light module, and a communication module.

The sensor module may detect an input by a user's body or an input by an input module, and generate an electrical signal or data value corresponding to the input. The sensor module may include at least one of a fingerprint sensor, an input sensor, and a digitizer. The sensor module may further include a gesture sensor, a gyro-sensor, a pressure sensor, a magnetic sensor, an acceleration sensor, a grip sensor, a proximity sensor, a color sensor, an infrared (IR) ray sensor, a vivo sensor, a temperature sensor, a humidity sensor, or an illuminance sensor.

The input module, the sensor module, the camera module, etc. may be used to control the operations of the display apparatus in conjunction with the processor.

The electronic apparatus may be of various types of devices. The electronic apparatus may include, for example, a portable communication apparatus (e.g., smartphone), a computer apparatus, a portable multimedia apparatus, a portable medical apparatus, a camera, a wearable device, or a home appliance. The electronic apparatus according to an embodiment of the disclosure is not necessarily limited to the above stated apparatuses.

The display apparatus according to one or more embodiments of the present disclosure may increase image quality characteristics and precisely control optical characteristics.

While the present disclosure has been particularly shown and described with reference to non-limiting embodiments thereof, it will be understood by those of ordinary skill in the art that various changes in form and details may be made therein without departing from the spirit and scope of the present disclosure.

What is claimed is:

1. A display apparatus comprising:
a substrate;
a first electrode on the substrate;
a second electrode arranged to face the first electrode;
a first emission layer arranged between the first electrode and the second electrode;
a second emission layer arranged to have a first region overlapping at least the first emission layer; and
a charge generation layer arranged between the first emission layer and the second emission layer, the charge generation layer including a charge connection region that does not overlap the first emission layer in a thickness direction of the substrate and overlaps the second emission layer in the thickness direction of the substrate.

2. The display apparatus of claim 1, wherein:
the second emission layer extends past at least an edge of the first emission layer and includes a second region that does not overlap the first emission layer in the thickness direction of the substrate.

3. The display apparatus of claim 1, wherein:
the second emission layer has a greater area in a plan view than an area of the first emission layer in the plan view.

4. The display apparatus of claim 1, wherein:
one or more insulating layers having a contact hole are arranged on the substrate; and
the charge connection region of the charge generation layer corresponds to the contact hole.

5. The display apparatus of claim 4, wherein:
the contact hole is arranged to be spaced apart from the first electrode in a plan view.

6. The display apparatus of claim 1, wherein:
the charge connection region of the charge generation layer is electrically connected to one or more conductive layers.

7. The display apparatus of claim 1, wherein:
the charge connection region of the charge generation layer is electrically connected to one or more transistors.

8. A display apparatus comprising:
a substrate;
a first electrode on the substrate;
a second electrode arranged to face the first electrode;
a first emission layer arranged between the first electrode and the second electrode;
a second emission layer arranged to have a first region overlapping at least the first emission layer; and
an intermediate electrode arranged between the first emission layer and the second emission layer, the intermediate electrode including a connection region that does not overlap the first emission layer in a thickness direction of the substrate and overlaps the second emission layer in the thickness direction of the substrate.

9. The display apparatus of claim 8, wherein:
the second emission layer extends past at least an edge of the first emission layer and includes a second region that does not overlap the first emission layer in the thickness direction of the substrate.

10. The display apparatus of claim 8, wherein:
the second emission layer has a greater area in a plan view than an area of the first emission layer in the plan view.

11. The display apparatus of claim 8, wherein:
one or more insulating layers having a contact hole are arranged on the substrate; and
the connection region of the intermediate electrode corresponds to the contact hole.

12. The display apparatus of claim 11, wherein:
the contact hole is arranged to be spaced apart from the first electrode in a plan view.

13. The display apparatus of claim 11, wherein:
the connection region of the intermediate electrode is electrically connected to one or more conductive layers in a region corresponding to the contact hole.

14. The display apparatus of claim 8, wherein:
the connection region of the intermediate electrode is arranged to be electrically connected to one or more transistors.

15. The display apparatus of claim 8, wherein:
the intermediate electrode controls one of the first emission layer and the second emission layer to selectively emit light.

16. An electronic device comprising a display apparatus,
wherein the display apparatus comprises:
a substrate;
a first electrode on the substrate;
a second electrode arranged to face the first electrode;
a first emission layer arranged between the first electrode and the second electrode;
a second emission layer arranged to have a region overlapping at least the first emission layer; and
a charge generation layer arranged between the first emission layer and the second emission layer, the charge generation layer including a charge connection region that does not overlap the first emission layer in a thickness direction of the substrate and overlaps the second emission layer in the thickness direction of the substrate.

17. The electronic device of claim 16, wherein:
the second emission layer extends past at least an edge of the first emission layer and includes a second region that does not overlap the first emission layer in the thickness direction of the substrate.

18. The electronic device of claim 16, wherein:
the second emission layer has a greater area in a plan view than an area of the first emission layer in the plan view.

19. The electronic device of claim 16, wherein:
one or more insulating layers having a contact hole are arranged on the substrate; and
the charge connection region of the charge generation layer corresponds to the contact hole.

20. The electronic device of claim 19, wherein:
the contact hole is arranged to be spaced apart from the first electrode in a plan view.
